(19) United States
(12) Patent Application Publication
(10) Pub. No.: US 2012/0176738 A1
(43) Pub. Date: Jul. 12, 2012

(54) HANDHELD ELECTRONIC DEVICE

(75) Inventor: Chih-Sheng Wei, Taoyuan County (TW)

(73) Assignee: HTC CORPORATION, Taoyuan County (TW)

(21) Appl. No.: 13/195,858

(22) Filed: Aug. 2, 2011

(30) Foreign Application Priority Data
Jan. 6, 2011 (TW) 100100498

(51) Int. Cl. H05K 7/00

(52) U.S. Cl. 361/679.01

(57) ABSTRACT

A handheld electronic device includes a first body having a first and a second ends opposite to each other, a second body disposed on the first body, a sliding bracket disposed between the first and the second body, a hinge, and a raising member. The second body is slidably disposed on the sliding bracket to rotate relative to the first body. The sliding bracket has a pivot portion away from the second end of the first body. The hinge is connected between the pivot portion and the first body. The raising member disposed at the second end of the first body leans against the sliding bracket to supply a rotating moment to the sliding bracket. The second body moves toward the second end of the first body to present a spreading status, and the rotating moment drives the second body to rotate along the hinge in the spreading status.

### CROSS-REFERENCE TO RELATED APPLICATION

This application claims the priority benefit of Taiwan application serial no. 100100498, filed on Jan. 6, 2011. The entirety of the above-mentioned patent application is hereby incorporated by reference herein and made a part of this specification.

### BACKGROUND

1. Field of the Application

The application relates to an electronic device. Particularly, the application relates to a handheld electronic device.

2. Description of Related Art

A handheld electronic device refers to an electronic device capable of being carried and operated by a user. The handheld electronic device generally has smaller size and weight to facilitate the user to carry around. The commonly used handheld electronic devices include mobile phones, multimedia players, personal digital assistants (PDAs), handheld game machines, handheld satellite navigators and notebook computers, etc. Taking the mobile phone as an example, the early mobile phone has a bar-type design. However, in order to increase carrying convenience of the mobile phone while maintaining a screen area and a keyboard area of the mobile phone, a folding-type and a slide-type mobile phones are developed.

Taking the slide-type mobile phone as an example, a sliding operation thereof may be implemented by relatively sliding two bodies thereof through a slide mechanism, so that one body can be rotated and raised relative to another body to present a standing pose, so as to achieve different appearance patterns of the two bodies.

In order to achieve the above motion, a plurality of components such as cams pivots or springs, etc. are required to be disposed in one of the bodies, and these members occupies a large space, so that the slide-type mobile phone may be hard to be lighted and thinned. Moreover, when the body is in the standing pose, and the user wants to operate the standing body (for example, operate a touch screen of the body), the body can be only supported by the aforementioned pivot, which may generally cause a poor operating sense due to a poor structure strength.

### SUMMARY

The application may be directed to a handheld electronic device, which has fewer components, a light and thin profile and better operating sense.

The application provides a handheld electronic device including a first body, a second body, a sliding bracket, a hinge and a raising member. The first body has a first end and a second end opposite to the first end. The second body may be disposed on the first body. The sliding bracket may be disposed between the first and the second body. The second body may be slidably disposed on the sliding bracket to slide relative to the first body. The sliding bracket has a pivot portion away from the second end of the first body. The hinge may be connected between the pivot portion of the sliding bracket and the first body. The raising member may be disposed at the second end of the first body and leans against the sliding bracket to supply a rotating moment to the sliding bracket. The second body may be adapted to move toward the second end of the first body to present a spreading status, and the rotating moment may be adapted to drive the second body to rotate along the hinge in the spreading status.

According to the above descriptions, in the handheld electronic device of the application, by disposing the sliding bracket and the raising member at one end of the first body, the first body may have more available space. Moreover, as the raising member leans against the sliding bracket, the raising member may supply a rotating moment to the sliding bracket to drive the second body to rotate along the hinge when the second body may be in the spreading status relative to the first body. In this way, the handheld electronic device may implement motion demands of sliding and rotating through a simple mechanism. Therefore, the handheld electronic device may be developed to be lighter and thinner.

In order to make the aforementioned and other features and advantages of the application comprehensible, several exemplary embodiments accompanied with figures are described in detail below.

### BRIEF DESCRIPTION OF THE DRAWINGS

The accompanying drawings are included to provide a further understanding of the application, and are incorporated in and constitute a part of this specification. The drawings illustrate embodiments of the application and, together with the description, serve to explain the principles of the application.

FIG. 1 is an exploded view of a handheld electronic device according to an embodiment of the application.

FIG. 2 to FIG. 4 are schematic diagrams of the handheld electronic device of FIG. 1 in different status.

FIG. 5 is a schematic diagram of a handheld electronic device according to another embodiment of the application.

### DETAILED DESCRIPTION OF DISCLOSED EMBODIMENTS

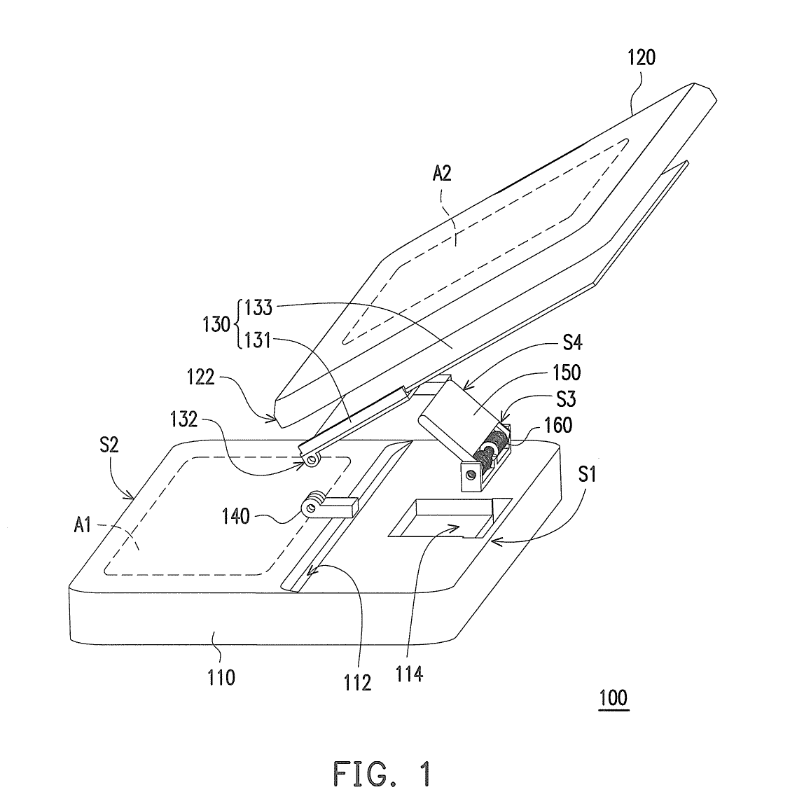

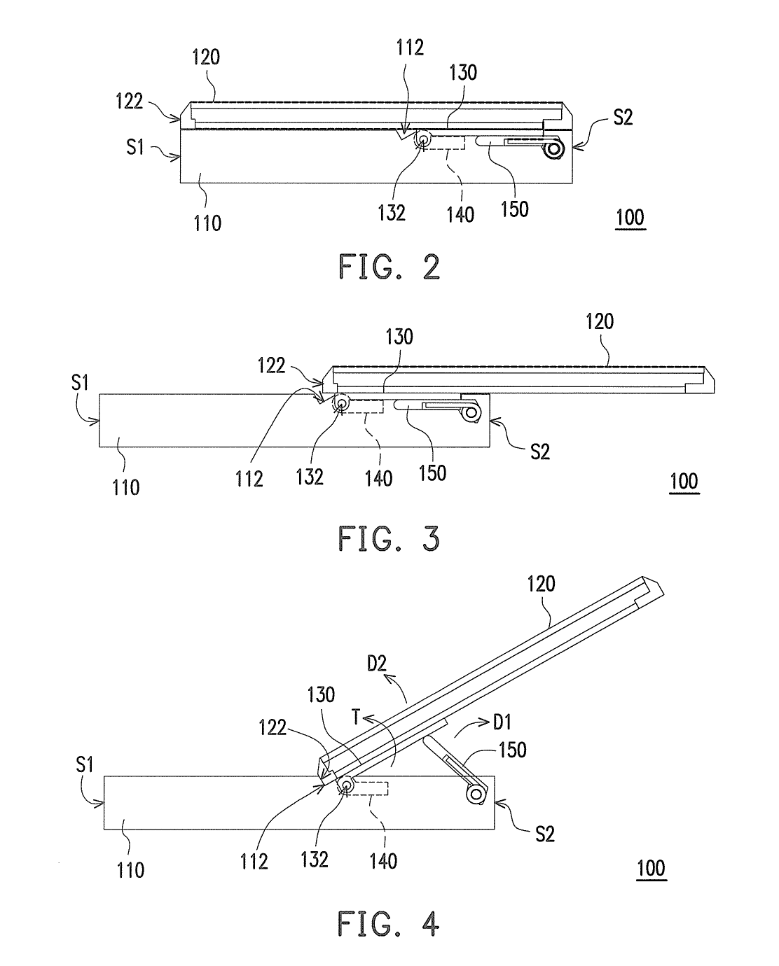

FIG. 1 is an exploded view of a handheld electronic device according to an embodiment of the application. FIG. 2 to FIG. 4 are schematic diagrams of the handheld electronic device of FIG. 1 in different status. Referring to FIG. 1 to FIG. 4, in the present embodiment, the handheld electronic device 100 includes a first body 110, a second body 120, a sliding bracket 130, a hinge 140 and a raising member 150. The first body 110 has a keyboard A1, and the second body 120 has a touch screen A2. When the first body 110 and the second body 120 are in a status shown in FIG. 2, a user may operate the handheld electronic device 100 through the touch screen A2, and when the first body 110 and the second body 120 are in a status shown in FIG. 4, the user may simultaneously operate the handheld electronic device 100 through the keyboard A1 and the touch screen A2, though the application is not limited thereto.

The first body 110 has a first end S1 and a second end S2 opposite to the first end S1. The second body 120 may be disposed on the first body 110. The sliding bracket 130 may be disposed between the first body 110 and the second body 120, and the second body 120 may be slidably disposed on the sliding bracket 130, so that the second body 120 may slide relative to the first body 110, and the handheld electronic device 100 may be switched between an overlapping status shown in FIG. 2 and a spreading status shown in FIG. 3. In the present embodiment, the sliding bracket 130 has a pivot portion 132 away from the second end S2 of the first body 110. The hinge 140 may be connected between the pivot portion 132 of the sliding bracket 130 and the first body 110. In detail, the sliding bracket 130 includes a first bracket 131 and a second bracket 133, where the first bracket 131 has the pivot portion 132 connected to the hinge 140, and the second body 120 may be fixed to the second bracket 133, and the second bracket 133 may be slidably connected to the first bracket 131, so that the second body 120 may slide relative to the first body 110, though a sliding mechanism of the sliding bracket 130 is not limited by the application.

The raising member 150 may be disposed at the second end S2 of the first body 110 and leans against the sliding bracket 130 to supply a rotating moment T to the sliding bracket 130. Therefore, when the second body 120 moves toward the second end S2 of the first body 110 to present the spreading status shown in FIG. 3, the rotating moment T drives the second body 120 to rotate along the hinge 140 in the spreading status, so that the raising member 150 drives the sliding bracket 130 and the second body 120 thereon to rotate relative to the first body, and the handheld electronic device 100 finally presents a standing status shown in FIG. 4.

According to the above descriptions, in the handheld electronic device 100 of the present embodiment, by disposing the sliding bracket 130 and the raising member 150 at one end of the first body 110, the first body 110 may have more available space. For example, an area of the keyboard A1 on the first body 110 may be enlarged to improve operability of the handheld electronic device 100. Moreover, as the raising member 150 leans against the sliding bracket 130, the raising member 150 may supply the rotating moment T to the sliding bracket 130 to drive the second body 120 to rotate along the hinge 140 when the second body 120 may be in the spreading status relative to the first body 110. In this way, the handheld electronic device 100 may implement motion demands of sliding and rotating through a simple mechanism, so that the handheld electronic device 100 may be developed to be lighter and thinner.

On the other hand, in the handheld electronic device 100 of the present embodiment, the first body 110 has a recess 112 located on a path where the second body 120 rotates along the hinge 140. When the raising member 150 drives the second body 120 to rotate relative to the first body 110, a side edge 122 of the second body 120 may be rotated into the recess 112, and since a profile of the side edge 122 may be complied with that of the recess 112, the second body 120 may be stopped by the recess 112, so that the second body 120 may be in the standing status relative to the first body 110 by an angle as that shown in FIG. 4. In the present embodiment, a designer may suitably adjust the angle between the second body 120 and the first body 110 by changing a position and a profile of the recess 112 on the first body 110.

It should be noticed that when the second body 120 may be in the standing status relative to the first body 110, the raising member 150 sustained between the sliding bracket 130 and the first body 110 substantially forms an angle with the sliding bracket 130, and such angle may be greater than 90 degrees and smaller than 180 degrees. In some cases, to ensure the raising member 150 stably supporting the first body 110, a position relationship between the sliding bracket 130 and the raising member 150 may approach a so-called “dead point position” of a mechanism system. The so-called “dead point position” refers to that a linkage mechanism may be in a stable state, which may be a state that an active member may be hard to drive a follower to move. In the present embodiment, the dead point position may be achieved when an angle formed between the sliding bracket 130 and the raising element 150 may be 90 degrees.

In the present embodiment, the position relationship between the sliding bracket 130 and the raising member 150 may approach the dead point position, so that the raising member 150 may provide good support for the sliding bracket 130. However, a situation that the position relationship between the sliding bracket 130 and the raising member 150 may be just the dead point position should be avoided, so as to avoid sticking of the sliding bracket 130 and the raising member 150. Therefore, the angle between the sliding bracket 130 and the raising member 150 may be substantially greater than 90 degrees and smaller than or equal to 180 degrees. In other words, the sliding bracket 130 may be located near but not just on the dead point position relative to the raising member 150. Particularly, the angle between the sliding bracket 130 and the raising member 150 may be within a range of greater than 90 degrees and smaller than or equal to 100 degrees. In this way, the raising member 150 may provide the sliding bracket 130 a larger normal supporting force.

Therefore, when the user presses the touch screen A2 to operate the handheld electronic device 100 in the standing status, the raising member 150 has an enough structure strength to support the sliding bracket 130 and the second body 120 to endure a pressing force of the user without influencing a relative movement of the first body 110 and the sliding bracket 130, so that the handheld electronic device 100 has a better operating sense in the standing status.

On the other hand, in the present embodiment, a first side S3 of the raising member 150 may be substantially pivoted in a recess portion 114 of the first body 110, and a second side S4 of the raising member 150 leans against the sliding bracket 130. Moreover, the handheld electronic device 100 further includes an elastic member 160, which is, for example, a torsion spring connected between the first side S3 of the raising member 150 and the first body 110. Here, the elastic member 160 may be a source of the rotating moment T supplied to the sliding bracket 130 by the raising member 150.

In other words, when the handheld electronic device 100 may be in the overlapping status shown in FIG. 2, the rotating moment T provided by the elastic member 160 may be limited by the mutual interference between the first body 110 and the second body 120, and the elastic member 160 may be in an elastic deformation state. Once the second body 120 may be slid relative to the first body 110 to the spreading status shown in FIG. 3, the elastic member 160 releases its elastic force to drive the raising member 150 to rotate relative to the first body 110 along a first direction D1, and meanwhile drive the sliding bracket 130 and the second body 120 thereon to rotate relative to the first body 110 along a second direction D2 opposite to the first direction D1.

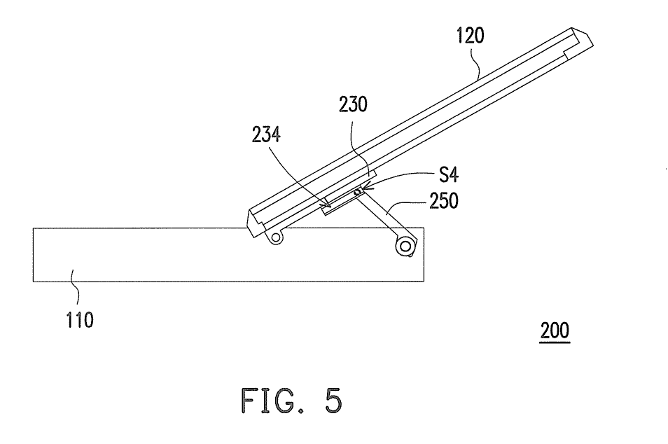

Here, a linkage structure between the raising member and the sliding bracket is not limited, and FIG. 5 is a schematic diagram of a handheld electronic device according to another embodiment of the application. Referring to FIG. 5, different to the aforementioned embodiment, in the handheld electronic device 200 of the present embodiment, a sliding slot 234 may be disposed on a sliding bracket 230 back to the second body 120, and a second side S4 of a raising member 250 may be slidably pivoted to the sliding slot 234. In this way, the raising member 250 and the sliding bracket 230 form a linkage mechanism having both of a sliding and a rotating effects, so as to achieve a same effect as that of the aforementioned embodiment.

In summary, in the handheld electronic device of the application, by disposing the sliding bracket and the raising member at one end of the first body, the first body may have more available space. Moreover, the raising member leans against the sliding bracket. When the second body is in the spreading status relative to the first body, the raising member may supply a rotating moment to the sliding bracket to drive the second body to rotate along the hinge, so that the second body may be switched from the spreading status to the standing status relative to the first body. In this way, the handheld electronic device may implement motion demands of sliding and rotating through a simple mechanism. Therefore, the handheld electronic device may be developed to be lighter and thinner.

It will be apparent to those skilled in the art that various modifications and variations may be made to the structure of the application without departing from the scope or spirit of the application. In view of the foregoing, it is intended that the application cover modifications and variations of this application provided they fall within the scope of the following claims and their equivalents.

What is claimed is:

1. A handheld electronic device, comprising:
a first body, having a first end and a second end opposite to the first end;
a second body, disposed on the first body;
a sliding bracket, disposed between the first and the second body, wherein the second body is slidably disposed on the sliding bracket to slide relative to the first body, and the sliding bracket has a pivot portion away from the second end of the first body;
a hinge, connected between the pivot portion of the sliding bracket and the first body; and
a raising member, disposed at the second end of the first body, and leaning against the sliding bracket to supply a rotating moment to the sliding bracket, wherein the second body is adapted to move toward the second end of the first body to present a spreading status, and the rotating moment is adapted to drive the second body to rotate along the hinge in the spreading status.

2. The handheld electronic device as claimed in claim 1, wherein the first body has a recess located on a path where the second body rotates along the hinge, and a side edge of the second body is adapted to rotate into and be stopped by the recess, so that the second body is in a standing status relative to the first body by an angle.

3. The handheld electronic device as claimed in claim 2, wherein a profile of the recess is complied with a profile of the side edge of the second body.

4. The handheld electronic device as claimed in claim 2, wherein an angle between the sliding bracket and the raising member is greater than 90 degrees and smaller than 180 degrees in the standing status.

5. The handheld electronic device as claimed in claim 4, wherein the angle between the sliding bracket and the raising member is greater than 90 degrees and smaller than or substantially equal to 180 degrees.

6. The handheld electronic device as claimed in claim 1, further comprising:
an elastic member, disposed between the raising member and the first body, and severing as a source of the rotating moment supplied to the sliding bracket by the raising member.

7. The handheld electronic device as claimed in claim 6, wherein the elastic member is adapted to drive the raising member to rotate relative to the first body, so as to push the sliding bracket to rotate along the hinge, wherein a rotating direction of the raising member is opposite to a rotating direction of the sliding bracket.

8. The handheld electronic device as claimed in claim 1, wherein the sliding bracket has a sliding slot back to the second body, and the raising member is slidably pivoted to the sliding slot.
